(19) United States
(12) Patent Application Publication
(10) Pub. No.: US 2006/0292731 A1
(43) Pub. Date: Dec. 28, 2006

(54) CMOS image sensor and manufacturing method thereof

(75) Inventor: Shang-Won Kim, Gyunggi-do (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU ELECTRONICS CO., LTD.

(21) Appl. No.: 11/474,399

(22) Filed: Jun. 26, 2006

(30) Foreign Application Priority Data
Jun. 27, 2005 (KR) 10-2005-0055586

(51) Int. Cl. H01L 21/00

(52) U.S. Cl. 438/57; 438/65

(57) ABSTRACT

A CMOS image sensor with improved performance through improved uniformity of micro-lens size and a method for manufacturing the same are provided. The CMOS image sensor includes photodiodes formed on a semiconductor substrate for producing charges consistent with a quantity of incident light, an interlayer insulation layer formed on an entire surface of the semiconductor substrate including the photodiodes , color filter layers formed in the interlayer insulation layer for passing light of respective wavelengths, and micro-lenses formed on the color filter layers for concentrating light onto the photodiodes through the color filter layers.

### CROSS-REFERENCE TO RELATED APPLICATION

This application claims priority of benefit to Korean Patent Application No. 10-2005-0055586 filed in the Korean Intellectual Property Office on Jun. 27, 2005, the entire contents of which are incorporated herein by reference.

### BACKGROUND

(a) Technical Field

The present invention relates to an image sensor, particularly a CMOS image sensor, and a manufacturing method thereof, that can improve the performance of the image sensor by improving a uniformity of micro-lens size.

(b) Description of the Related Art

An image sensor is a kind of semiconductor device that can convert optical images into an electrical signal. Generally, image sensors can be divided into charge coupled device (CCD) image sensors and complementary metal oxide semiconductor (CMOS) image sensors.

A CMOS image sensor is composed of a photodiode for sensing light and a CMOS logic circuit for converting the sensed light into electrical data. Photosensitivity is improved if more photons are received by the photodiode.

In order to enhance the photosensitivity, the ratio of the photodiode area to the entire image sensor area, namely Fill Factor, is increased, or the path of light is modulated so as to concentrate the light to the photodiode.

A typical method of concentrating the light is by use of one or more micro-lenses, so that light is refracted and focused onto the photodiode.

When a plurality of micro-lenses are used, it is important to control the exposure and development conditions uniformly.

Now, a conventional CMOS image sensor and a method of manufacturing the same is described in detail with reference to the accompanying drawings.

FIG. 1 is a cross-sectional view showing a typical CMOS image sensor.

As shown in FIG. 1, a typical CMOS image sensor includes: photodiode regions 11 that are formed on a semiconductor substrate (not shown) to produce charges corresponding to the quantity of incident light; an interlayer insulation layer 12 formed on the entire surface of the substrate including the photodiode regions 11; a protective layer 13 formed on the interlayer insulation layer 12; color filter layers 14 of RGB color (i.e., red, green, and blue) that are formed on the protective layer 13 and respectively pass light having predetermined wavelengths; a planarization layer 15 formed on the entire surface of the color filter layers 14; and micro-lenses 16 having convex shapes of predetermined curvature that are formed on the planarization layer 15 so as to concentrate light to the photodiode regions 11 via the color filter layers 14.

Although not shown in the drawing, an optical shielding layer for preventing light from being incident on regions other than the photodiode regions 11 is formed in the interlayer insulation layer 12.

The photodiode may be replaced with a photo gate for sensing light.

The curvature and the height of the micro-lenses 16 are chosen based on various factors such as focus of concentrated light. The micro-lenses 16 are formed by sequential processes such as coating a photoresist layer for micro-lenses, patterning by exposing and developing, and re-flowing.

The micro-lenses should have an optimal size, thickness, and curvature radius that are determined by the size, the location, the shape of a unit pixel, the thickness of the light sensing device, the height, the location, and the size of the optical shielding layer, and so on.

Pattern profiles of conventional CMOS image sensors may vary because of variations in the exposure condition during manufacture. For example, processing conditions may cause variation in the condition of a thin film on the semiconductor substrate. Accordingly, the micro-lenses may also be varied. The processing conditions of forming patterns may be very unstable, so the efficiency of concentrating light can be deteriorated.

As described above, in the process of forming the typical CMOS image sensor, the micro-lenses 16 for enhancing the efficiency of concentrating lights are a major factor that determines the characteristics of the image sensor.

The light incident onto the photodiode region 11 is concentrated by the micro-lenses 16, filtered via the color filter layers 14. Each micro-lens 16 has a role of concentrating more light onto the photodiode region 11 via each color filter layer 14 when natural light is incident.

The optical shielding layer prevents the incident light from deviating from the determined path.

FIG. 2A to FIG. 2D are cross-sectional views showing principal stages of manufacturing a conventional CMOS image sensor.

As shown in FIG. 2A, an interlayer insulation layer 12 is formed on a semiconductor substrate wherein a plurality of light detecting devices such as photodiodes 11 are formed.

The interlayer insulation layer 12 can be formed as a multi-layer. For example, the interlayer insulation layer 12 may be formed by forming a first interlayer insulation layer, forming an optical shielding layer on the first interlayer insulation layer to prevent light from being incident on regions other than the photodiode regions 11, and forming a second interlayer insulation layer on the optical shielding layer.

Subsequently, a protective layer 13 for protecting the device from moisture and scratch is formed on the interlayer insulation layer 12 and planarized.

A photoresist is coated on the protective layer 13 and patterned by an exposing and developing process so as to form color filter layers 14 that can filter light according to different wavelengths.

Subsequently, a planarization layer 15 for providing adequate planarity is formed on the color filter layers 14.

Referring to FIG. 2B, a photoresist layer 16a for forming micro-lenses is coated on the planarization layer 15. A photo mask 17 having openings is provided above and aligned to the photoresist layer 16a.

Subsequently, the photoresist layer 16a is selectively exposed by illuminating light through the openings of the photo mask 17.

As shown in FIG. 2C, the exposed photoresist layer 16a is developed so as to form a micro-lens pattern 16b.

As shown in FIG. 2D, the micro-lens pattern 16b is re-flowed at a predetermined temperature so as to form micro-lenses 16.

However, the CMOS image sensor and the manufacturing method thereof as described above have some drawbacks as described below.

The photoresist layer for forming the color filter layers 14 is generally a negative resist, i.e., the regions unexposed are developed by a developing solution. The range of viscosity that influences a thickness of the photoresist layer is strictly limited.

Accordingly, it is difficult to realize various thicknesses that are necessary in processing. If various photoresists are used for acquiring the necessary thickness, the process is complicated.

Particularly, if a blue photoresist is thick, the exposure light cannot pass therethrough, so the adherence to an under layer is deteriorated and pattern peeling may occur.

In addition, when micro-lenses after are formed after the color filter layers 14, the sizes of the micro-lenses may be non-uniformly.

In particular, the micro-lenses may have irregular spacing therebetween and incomplete curvature. Moreover, because the micro-lenses cannot be formed directly on the color filter layers, a planarization layer should be formed between the color filters and the micro-lenses, and so the total thickness of the image sensor is enlarged and the efficiency of concentrating light is deteriorated.

The above information disclosed in this Background section is only for enhancement of understanding of the background of the invention and therefore it may contain information that does not form the prior art that is already known in this country to a person of ordinary skill in the art.

### SUMMARY

The present invention provides a CMOS image sensor with improved performance through improved uniformity of micro-lens size and a method for manufacturing the same.

A CMOS image sensor consistent with the present invention includes photodiodes formed on a semiconductor substrate for producing charges consistent with a quantity of incident light, an interlayer insulation layer formed on an entire surface of the semiconductor substrate including the photodiodes, color filter layers formed in the interlayer insulation layer for passing light of respective wavelengths, and micro-lenses formed on the color filter layers for concentrating light onto the photodiodes through the color filter layers

A method for manufacturing a CMOS image sensor consistent with embodiments of the present invention includes forming a plurality of photodiodes on a semiconductor substrate; forming an interlayer insulation layer on the semiconductor substrate including the photodiodes; forming a photoresist layer on the interlayer insulation layer; patterning the photoresist layer to form a photoresist pattern exposing portions of the interlayer insulation layer; forming a plurality of trenches having a first predetermined depth in the interlayer insulation layer using the photoresist pattern as an etching mask; removing the photoresist pattern; forming a plurality of color filter layers in the plurality of trenches; and forming a plurality of micro-lenses on the plurality of color filter layers.

### BRIEF DESCRIPTION OF THE DRAWINGS

FIG. 1 is a cross-sectional view showing a typical CMOS image sensor.

FIG. 2A to FIG. 2D are cross-sectional views showing principal stages of manufacturing a conventional CMOS image sensor.

FIG. 3A is a cross-sectional view showing a CMOS image sensor consistent with the present invention.

FIG. 3B is a cross-sectional view showing a CMOS image sensor consistent with the present invention.

FIG. 4A to FIG. 4G are cross-sectional views showing principal stages of manufacturing a CMOS image sensor consistent with the present invention.

FIG. 5 is a plan view of lattices surrounding micro-lenses in forming a CMOS image sensor consistent with the present invention.

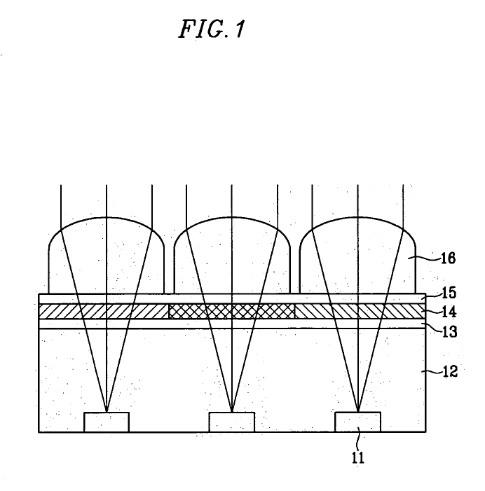

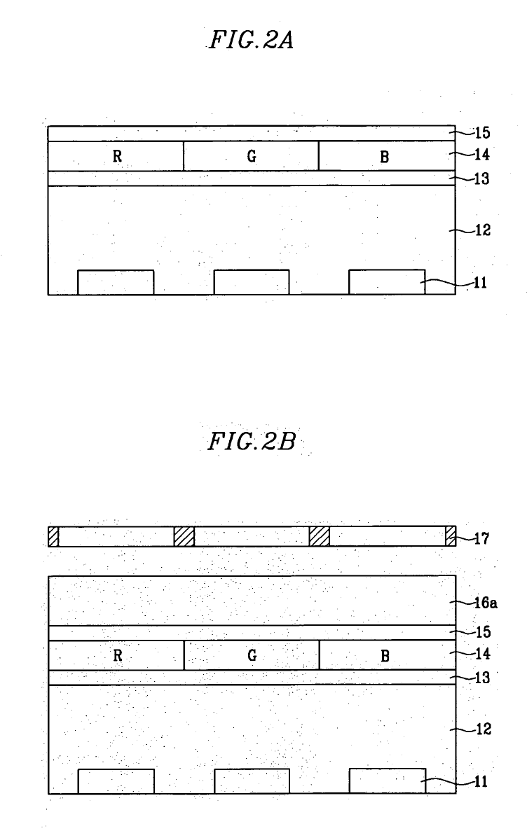

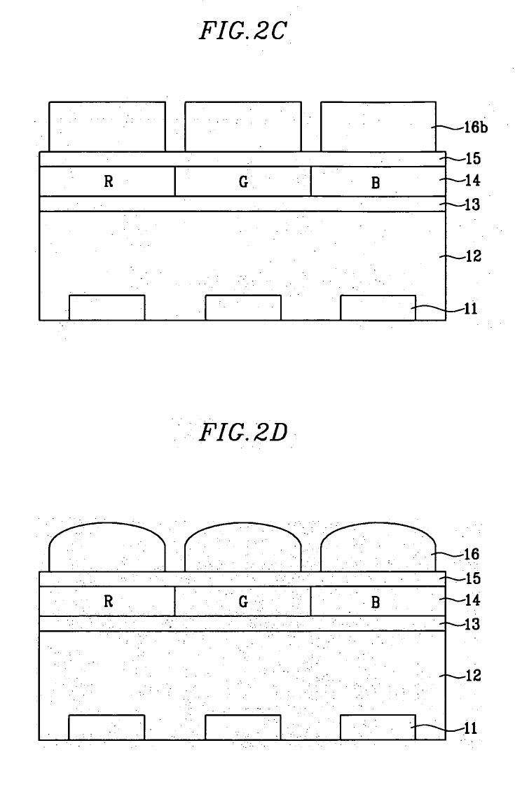

### DETAILED DESCRIPTION OF THE EMBODIMENTS

The present invention now will be described more fully hereinafter with reference to the accompanying drawings. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present. Where an element is described as “higher” or “lower,” each description is with respect to the substrate.

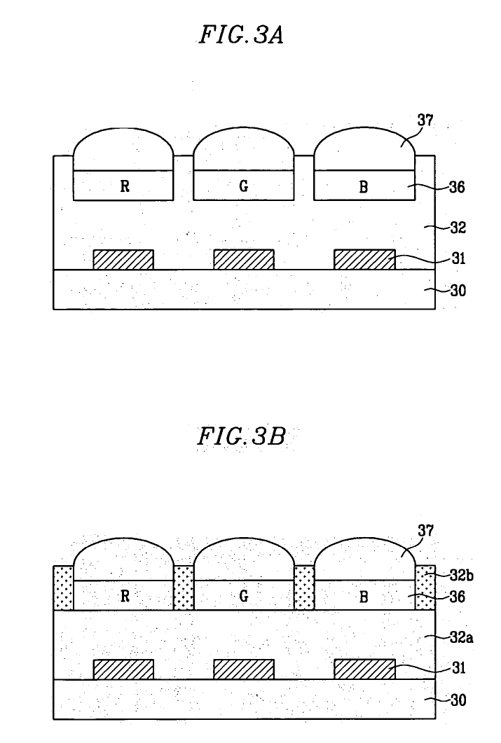

FIG. 3A is a cross-sectional view showing a CMOS image sensor consistent with a first embodiment of the present invention.

As shown in FIG. 3A, a CMOS image sensor includes: photodiodes 31 formed on a semiconductor substrate 30 for producing charges consistent with the quantity of incident light, an interlayer insulation layer 32 formed on the entire surface of the semiconductor substrate 30 including the photodiodes 31, color filter layers 36 of colors such as RGB, i.e., red, green, and blue, formed in the interlayer insulation layer 32 for respectively passing light having predetermined wavelengths, and micro-lenses 37 having convex shapes of predetermined curvature formed on the color filter layers 36 so for concentrating light onto the photodiodes 31.

FIG. 3B is a cross-sectional view showing a CMOS image sensor consistent with a second embodiment of the present invention.

As compared to the first embodiment, the CMOS image sensor consistent with the second embodiment of the present invention includes, instead of the interlayer insulation layer 32 as shown in FIG. 3A, a passivation layer 32a for protecting photodiode regions 31 and an optical shielding layer 32b formed on the passivation layer 32a. The optical shielding layer 32b can prevent light from being incident on regions other than the photodiodes 31. As a result, a color noise is reduced. The optical shielding layer 32b may comprise silicon nitride or SiON.

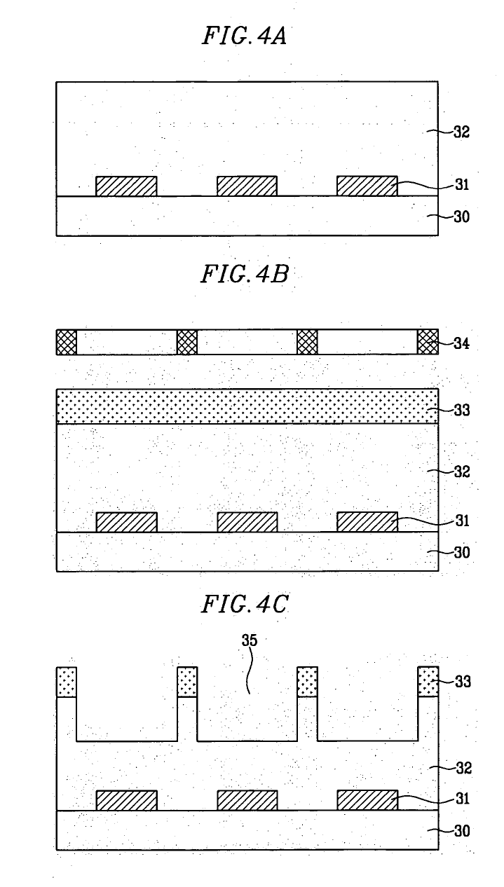

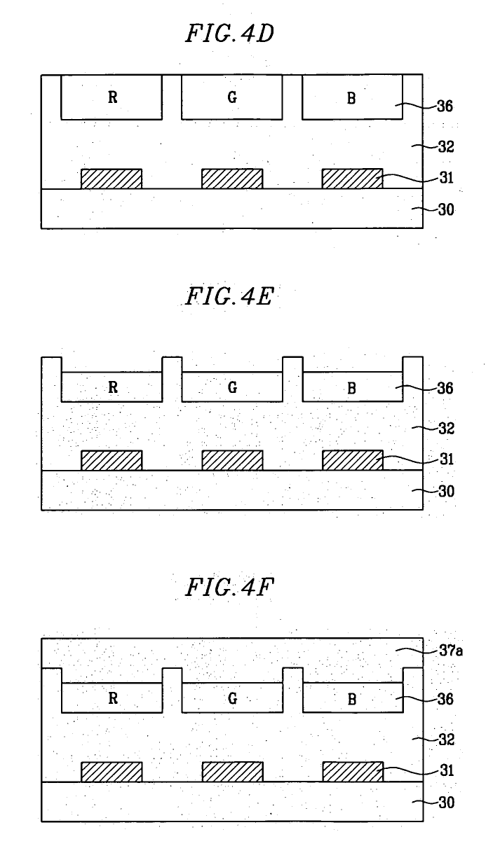

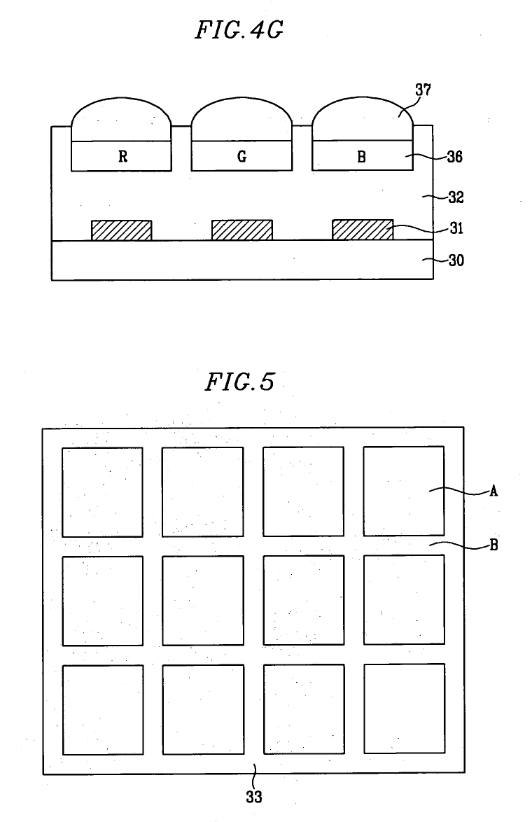

FIG. 4A to FIG. 4G are cross-sectional views showing principal stages of manufacturing a CMOS image sensor consistent with the present invention, and FIG. 5 is a plan view of lattices surrounding micro-lenses in forming the CMOS image sensor.

Referring to FIG. 4A, an interlayer insulation layer 32 is formed on a semiconductor substrate 30 wherein a plurality of light detecting devices such as photodiodes 31 are formed. The interlayer insulation layer 32 may be a multi-layer formed by forming a first interlayer insulation layer, forming an optical shielding layer on the first interlayer insulation layer for preventing light from being incident on regions other than the photodiodes 31, and forming a second interlayer insulation layer on the optical shielding layer.

Alternatively, referring to FIG. 3B and consistent with the second embodiment of the present invention, the interlayer insulation layer 32 may be formed by first forming a passivation layer 32a for protecting the photodiode regions 31 and then forming an optical shielding layer 32b on the passivation layer 32a. The optical shielding layer 32b may comprise silicon nitride or SiON.

As shown in FIG. 4B, an MUV photoresist 33, i.e., a photoresist that reacts to an I-line light, i.e., light having wavelength of 365 nm, is coated on the interlayer insulation layer 32. Subsequently, a photo mask 34 is provided over and aligned to the MUV photoresist 33. The MUV photoresist 33 is selectively exposed by illuminating light through the photo mask 34.

As shown in FIG. 4C, the exposed portion of the MUV photoresist 33 is developed so as to form a predetermined pattern. The predetermined pattern is shown in FIG. 5 as including micro-lens regions A and a lattice B surrounding the micro-lens regions A.

Subsequently, a plurality of trenches 35 having a predetermined depth from the surface of the interlayer insulation layer 32 are formed by selectively removing the interlayer insulation layer 32 using the patterned MUV photoresist 33 as an etching mask. Each of the trenches 35 corresponds to one of the photodiodes 31. The predetermined depth of the trenches 35 is about 1.2-1.4 μm, while a thickness of the color filter layers 36 to be formed subsequently ranges between about 0.7-0.9 μm, and the sum of thicknesses of the micro-lenses 37 and the color filter layers 36 ranges between about 1.4-1.6 μm. In other words, the depth of the trenches 35 is greater than the thickness of the color filter layers 36, but less than the sum of thicknesses of the micro-lenses 37 and the color filter layers 36. Therefore, top surfaces of the color filter layers 36 are lower than an upper surface of the interlayer insulation layer 32, but top surfaces of the micro-lenses 37 are higher than the upper surface of the interlayer insulation layer 32.

As shown in FIG. 4D, the MUV photoresist 33 is removed, and a resist layer is coated on the entire surface of the semiconductor substrate including the trenches 35. The resist layer is then exposed and developed, thereby forming color filter layers 36 of RGB color that filter light according to different wavelengths. At this time, each of the color filter layers 36 is formed such that a surface thereof is aligned with the upper surface of the interlayer insulation layer 32.

As shown in FIG. 4E, each of the color filter layers 36 is partially removed by an etching process, such as an ashing process, such that top surfaces of the color filter layers 36 are lower than the upper surface of the interlayer insulation layer 32 by approximately 0.4-0.6 μm. The predetermined thickness of the removed portion of the color filter layers 36 may vary depending on a desired depth for subsequently formed micro-lenses.

As shown in FIG. 4F, a resist 37a for forming micro-lenses is deposited on the entire surface of the interlayer insulation layer 32 including the color filter layers 36.

As shown in FIG. 4G, the resist 37a is selectively exposed by using the photomask 34, which was used to form the trenches 35. Subsequently, a micro-lens pattern is formed by developing the exposed resist 37a and re-flowed so as to form micro-lenses 37 of hemispherical shape. The re-flow process can be performed using a hot plate or furnace. According to a heating method for contracting the resist 37a, the curvature of the micro-lenses 37 may vary, and the concentrating efficiency of the micro-lenses 37, which varies with the curvature thereof, also vanes.

Subsequently, the micro-lenses 37 are hardened by irradiating ultraviolet rays thereon for maintaining optimum curvature radius.

In addition, by forming the trenches 35 having a depth greater than the thickness of the color filter layers 36, but less than the sum of thicknesses of the micro-lenses 37 and the color filter layers 36, the curvature of the micro-lenses 37 is also optimized.

A CMOS image sensor and a manufacturing method thereof according to the present invention may have the following effects.

First, because color filter layers 36 and micro-lenses 37 are formed in trenches 35, the size of the micro-lenses 37 can be controlled without an additional spacing control and pattern peeling of the color filter layers 36.

Second, the concentrating efficiency and uniformity of the micro-lenses 37 can be improved by skipping a planarization layer between the micro-lenses 37 and the color filter layers 36.

Third, the uniformity of the size of the micro-lenses 37 can be improved in a manufacturing process of an image sensor, and so the photosensitivity of the image sensor can be improved.

Fourth, an exposure condition for forming micro-lenses can be stabilized so that a yield is improved.

Fifth, compared with the conventional method, wherein exposure conditions for forming micro-lenses varied according to the condition of the under layer, the present invention can minimize the variation of the critical dimension of the micro-lenses.

While this invention has been described in connection with what is presently considered to be embodiments of the present invention, it is to be understood that the invention is not limited to the disclosed embodiments, but is intended to cover various modifications and equivalent arrangements included within the spirit and scope of the appended claims.

What is claimed is:

1. A CMOS image sensor, comprising:
a plurality of photodiodes formed on a semiconductor substrate for producing charges consistent with a quantity of incident light;
an interlayer insulation layer formed on an entire surface of the semiconductor substrate including the plurality of photodiodes;
a plurality of color filter layers formed in the interlayer insulation layer for passing light of respective wavelengths; and
a plurality of micro-lenses formed on the plurality of color filter layers for concentrating light onto the plurality of photodiodes through the plurality of color filter layers.

2. The CMOS image sensor of claim 1, wherein top surfaces of the color filter layers are lower than an upper surface of the interlayer insulation layer.

3. The CMOS image sensor of claim 1, wherein top surfaces of the micro-lenses are higher than an upper surface of the interlayer insulation layer.

4. The CMOS image sensor of claim 1, wherein the color filter layers are formed in a plurality of trenches in the interlayer insulation layer, and wherein a depth of the trenches is about 1.2-1.4 μm, a thickness of the color filter layers is about 0.7-0.9 μm, and a sum of a thickness of the micro-lenses and the thickness of the color filter layers is about 1.4-1.6 μm.

5. The CMOS image sensor of claim 1, wherein the interlayer insulation layer comprises a passivation layer for protecting the photodiodes and an optical shielding layer formed on the passivation layer.

6. The CMOS image sensor of claim 5, wherein the optical shielding layer comprises silicon nitride or SiON.

7. A method for manufacturing a CMOS image sensor, comprising:
forming a plurality of photodiodes on a semiconductor substrate;
forming an interlayer insulation layer on the semiconductor substrate including the photodiodes;
forming a photoresist layer on the interlayer insulation layer;
patterning the photoresist layer to form a photoresist pattern exposing portions of the interlayer insulation layer;
forming a plurality of trenches having a first predetermined depth in the interlayer insulation layer using the photoresist pattern as an etching mask;
removing the photoresist pattern;
forming a plurality of color filter layers in the plurality of trenches; and
forming a plurality of micro-lenses on the plurality of color filter layers.

8. The manufacturing method of claim 7, further comprising hardening the micro-lenses by irradiating ultraviolet rays.

9. The manufacturing method of claim 7, wherein forming the photoresist layer comprises forming an MUV photoresist layer, wherein an MUV photoresist reacts to an I-line light.

10. The manufacturing method of claim 7, wherein forming the micro-lenses comprises coating a resist on the interlayer insulation layer including the color filter layers therein, forming a micro-lens pattern by exposing and developing the resist, and re-flowing the micro-lens pattern.

11. The manufacturing method of claim 7, further comprising partially removing the color filter layers in the trenches.

12. The manufacturing method of claim 11, wherein partially removing the color filter layers comprises removing the color filter layers such that an upper surface of the interlayer insulation layer by approximately 0.4-0.6 μm.

13. The manufacturing method of claim 11, wherein partially removing the color filter layers comprises performing an ashing process.

14. The manufacturing method of claim 7, wherein forming the color filter layers comprises forming the color filter layers with a thickness less than a depth of the trenches.

15. The manufacturing method of claim 7, wherein forming the micro-lenses comprises forming the micro-lenses such that top surfaces of the micro-lenses are higher than an upper surface of the interlayer insulation layer.

16. The manufacturing method of claim 7, wherein forming the trenches comprises forming the trenches to be about 1.2-1.4 μm deep, forming the color filter layers comprises forming the color filter layers to be about 0.7-0.9 μm thick, and forming the color filter layers and forming the micro-lenses comprise forming the color filter layers and the micro-lenses such that a sum of the thicknesses thereof is about 1.4-1.6 μm.

17. The CMOS image sensor of claim 7, wherein forming the interlayer insulation layer comprises forming a passivation layer for protecting photodiode regions and forming an optical shielding layer on the passivation layer.

18. The CMOS image sensor of claim 17, wherein forming the optical shielding layer comprises forming a silicon nitride layer or a SiON layer.
